(19) United States
(12) Patent Application Publication
(10) Pub. No.: US 2023/0282450 A1
(43) Pub. Date: Sep. 7, 2023

(54) REMOTE PLASMA SOURCE SHOWERHEAD ASSEMBLY WITH ALUMINUM FLUORIDE PLASMA EXPOSED SURFACE

(71) Applicant: LAM RESEARCH CORPORATION, Fremont, CA (US)

(72) Inventors: Eric A. PAPE, Santa Cruz, CA (US); Shih-Chung KON, Fremont, CA (US); Pankaj HAZARIKA, Sherwood, OR (US); Lin XU, Fremont, CA (US)

(21) Appl. No.: 18/011,582

(22) PCT Filed: Jun. 24, 2021
(86) PCT No.: PCT/US2021/038848

§ 371 Date: Dec. 20, 2022

Related U.S. Application Data
(60) Provisional application No. 63/046,088, filed on Jun. 30, 2020.

(51) Int. Cl. H01J 37/32; C23C 16/455; C23C 16/30

(52) U.S. Cl. CPC H01J 37/32477; H01J 37/32422; H01J 37/32357; C23C 16/45536; C23C 16/30; H01J 37/32816; H01J 2237/334; C23C 8/08

(57) ABSTRACT

A component of a processing chamber in a substrate processing system includes a base material comprising aluminum, the base material having one or more surfaces, a diffusion barrier layer formed on the surfaces of the base material, wherein the diffusion barrier layer includes magnesium and fluorine (F), and a coating formed on the surfaces. The diffusion barrier layer is arranged between the surfaces and the coating and the coating includes fluorine.

### CROSS-REFERENCE TO RELATED APPLICATIONS

This application claims the benefit of U.S. Provisional Application No. 63/046,088, filed on Jun. 30, 2020. The entire disclosure of the application referenced above is incorporated herein by reference.

### FIELD

The present disclosure relates to protecting showerhead assemblies in remote plasma source substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform treatments on substrates such as semiconductor wafers. Examples of the treatments include deposition, etching, cleaning, etc. The substrate processing systems typically include a processing chamber including a substrate support, a gas delivery system and a plasma generator.

During processing, the substrate is arranged on the substrate support. Different gas mixtures may be introduced by the gas delivery system into the processing chamber. In some applications, radio frequency (RF) plasma such as inductively coupled plasma (ICP) may be used to activate chemical reactions.

ICP produces both highly reactive neutral species and ions to modify wafer surfaces. As customer devices become increasingly complicated and sensitive, controlling exposure of the substrate to the plasma is increasingly important. Ions generated within the plasma can have damaging effects on sensitive materials within device structures. The ions can modify the properties of device materials and adversely affect the performance of the overall structure.

### SUMMARY

A method of performing a fluoroconversion process to apply a coating to surfaces of a component of a substrate processing system includes arranging the component within a processing chamber, setting at least one process parameter of the processing chamber, selecting a fluorine-containing gas to react with a base material of the component on surfaces of the component, and flowing the fluorine-containing gas into the processing chamber for a first period. The fluorine-containing gas reacts with the base material on the surfaces of the component to form the coating on the surfaces and the coating is comprised of the base material of the component and fluorine.

In other features, the base material of the component is aluminum. The coating comprises aluminum fluoride. The fluorine-containing gas includes at least one of nitrogen trifluoride (NF₃), carbon tetrafluoride (CF₄), difluorine (F₂), methyl fluoride (CH₄₋ₓFₓ, where x is an integer from 1 to 3), sulfur hexafluoride (SF₆), and chlorine trifluoride (ClF₃). The at least one process parameter is a pressure within the chamber and the pressure is set in a range of 100 to 5000 mTorr. The at least one process parameter is a temperature within the chamber and the temperature is set in a range of 20 to 650 degrees Celsius. The coating has a thickness in a range of 20 nm to 5 microns.

In other features, the method further includes generating plasma within the processing chamber during the first period. The first period is between 1 and 100 hours. The component is a showerhead comprising an upper plate and a lower plate. The coating has a crystal lattice structure. The base material of the component is an aluminum alloy comprising magnesium and flowing the fluorine-containing gas into the processing chamber reacts with the magnesium to form a diffusion barrier layer between the surfaces of the component and the coating.

A method of performing a fluoroconversion process to apply a coating to surfaces of a component of a substrate processing system includes arranging the component within a first processing chamber. The component comprises aluminum. The method further includes flowing a fluorine-containing gas into the first processing chamber for a first period and generating plasma within the first processing chamber during the first period. The fluorine-containing gas is selected to react with the aluminum on the surfaces of the component to form the coating on the surfaces and the coating comprises aluminum fluoride.

In other features, the method further includes removing the component from the first processing chamber and installing the component in a second processing chamber. The method further includes, prior to flowing the fluorine-containing gas into the first processing chamber, forming an anodized passivation layer on the surfaces of the component. The fluorine-containing gas reacts with the anodized passivation layer to form one of aluminum fluoride, aluminum oxyfluoride, and mixed phases of aluminum fluoride and aluminum oxyfluoride.

In other features, prior to flowing the fluorine-containing gas into the first processing chamber, the surfaces of the component have a surface roughness Ra between 2.5 and 25 μm. The component further comprises magnesium, and wherein flowing the fluorine-containing gas into the first processing chamber reacts with the magnesium to form a diffusion barrier layer between the surfaces of the component and the coating.

A method of performing an atomic layer deposition (ALD) process to apply a coating to surfaces of a component of a substrate processing system includes arranging the component within a processing chamber and flowing a first precursor into the processing chamber for a first period. The first precursor includes a base material of the component. The method further includes flowing at least a second precursor into the processing chamber for a second period. The second precursor includes fluorine, the first precursor and the second precursor are selected to react with the surfaces of the component to form the coating on the surfaces, and the coating is comprised of the base material of the component and fluorine.

In other features, the base material of the component is aluminum. The coating comprises aluminum fluoride. The first precursor includes aluminum chloride (AICl₃). The second precursor includes at least one of titanium fluoride (TiF₄) and tantalum fluoride (TaF₅). The coating has a thickness in a range of 10 nm to 200 nm. The method further includes generating plasma within the processing chamber during at least one of the first period and the second period. The component is a showerhead comprising an upper plate and a lower plate.

A showerhead for a processing chamber in a substrate processing system includes an upper plate and a lower plate. At least one of the upper plate and the lower plate is comprised of an aluminum (Al) alloy including magnesium (Mg). A diffusion barrier layer is formed on surfaces of at least one of the upper plate and the lower plate. The diffusion barrier layer includes magnesium and fluorine (F). A coating is formed on the surfaces. The diffusion barrier layer is arranged between the surfaces and the coating and the coating includes fluorine. The diffusion barrier layer is comprised of MgF₂ and the coating is comprised of AlF₃.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagrams of examples of a substrate processing system including a showerhead according to the present disclosure;

FIGS. 2A and 2B show example showerheads including an upper plate and a lower plate according to the present disclosure;

FIG. 2C shows an example lower plate of a showerhead according to the present disclosure;

FIG. 2D shows an example upper plate of a showerhead according to the present disclosure;

FIG. 3 shows steps of an example method for applying a coating to components of a showerhead using a conformal ALD process according to the present disclosure; and

FIG. 4 shows steps of an example method for applying a coating to components of a showerhead using a conformal fluoroconversion process according to the present disclosure.

In the drawings, reference numbers may be reused to identify similar and/or identical elements.

### DETAILED DESCRIPTION

Remote plasma substrate processing systems include a distribution device such as showerhead assembly arranged between an upper region of a processing chamber where plasma is generated and a lower region of the processing chamber where a substrate is located. The showerhead assembly may be configured to function as a filter (e.g., a dual ion filter) for blocking or filtering ions and/or ultraviolet (UV) light. For example, the showerhead assembly may comprise a single piece or upper and lower plates (e.g., upper and lower filters). The upper plate or filter may be configured to primarily filter ions generated by the plasma. Conversely, the lower filter may be configured to primarily control plasma uniformity.

The showerhead assembly reduces a number of ions reaching the substrate by increasing an electrically grounded area to capture ions, increasing surface area to help recombination, and decreasing a mean free path to facilitate recombination. For example, surfaces of the showerhead assembly are configured as one or more grids that eliminate line of sight between a plasma source and the substrate. Further, the showerhead may be electrically DC grounded and have vacuum facing surfaces that have consistent (e.g., part-to-part consistency and consistency over time) recombination coefficients for radical species in the plasma.

Components of the showerhead may be comprised of aluminum to provide electrical conductivity for DC grounding and ion extraction. For example, the components of the showerhead assembly may comprise bare aluminum. In other examples, the components may be hard coat anodized (e.g., type III aluminum anodized), coated with a native oxide layer (e.g., an aluminum oxide (alumina, or Al₂O₃) and/or yttrium oxide (Y₂O₃) mixture), etc. The coating may be applied using atomic layer deposition (ALD).

Aluminum surfaces that are hard coat anodized may have a high content of surface-exposed boehmite and high surface roughness, which may result in increased fluorination of the surfaces over time when exposed to plasma containing fluorine precursors. Fluorination changes concentration gradients from a gas partial pressure to the substrate, which reduces an amount of fluorine radicals available to react with the substrate and create metal fluoride bonds (e.g., AlₓO_{y}F_{z} compositions of materials with unknown and uncontrollable physical properties). Further, modification of the surfaces changes hydrogen radical recombination coefficients relative to initial conditions of surface-exposed materials (e.g., hydroxyl groups, oxygen, aluminum, etc. on the surfaces). These changes over time lead to instability in etch processes. For example, etch rates may vary 20% or more over several hundred RF hours of an operation time of the processing chamber. In some conditions, aluminum fluoride (AlF₃) in the surface-exposed boehmite may cause aluminum fluoride particle contamination. In some examples, uncontrolled fluorination results in the creation of porous, low-density aluminum fluoride on the surfaces.

Conversely, etch rates using showerhead assemblies having ALD oxide coatings (e.g., alumina and/or yttrium oxides) may have greater stability due to a moderate or lower rate of fluorination. However, ALD oxide coatings may be susceptible to chipping and may be difficult to clean. Further, some etch processes may be difficult to tune when ALD oxide coatings or native oxide coatings are used due to low radical recombination rates.

Systems and methods according to the present disclosure implement a conformal coating configured to maintain consistent interaction between surfaces of the showerhead assembly and process materials (e.g., plasma). For example, the coating is an aluminum fluoride coating that is applied to vacuum-facing surfaces of the showerhead assembly and has a thickness in a range of 20 nm to 5 microns (i.e., μm), or, preferably, a range of 0.5 to 2.0 microns. The aluminum fluoride surface maintains consistent, desired radical recombination rates over time. For example, the aluminum fluoride surface is applied outside of the processing chamber (i.e., ex situ).

In some examples, an ALD process may be used to apply the coating to a substrate material (e.g., aluminum) of components of the showerhead assembly. The ALD process may be used to apply a relatively thin coating (e.g., less than 100 nm). In other examples, a fluoroconversion process is performed on an outer layer of the substrate material to generate an aluminum fluoride coating (e.g., a coating having a thickness in a range of 20 nm to 5 microns, or, preferably, a range of 0.5 to 2.0 microns). Performance and material characteristics (e.g., etch rates, component lifetime, ease of cleaning, etc.) may vary based on which process is used to apply the coating.

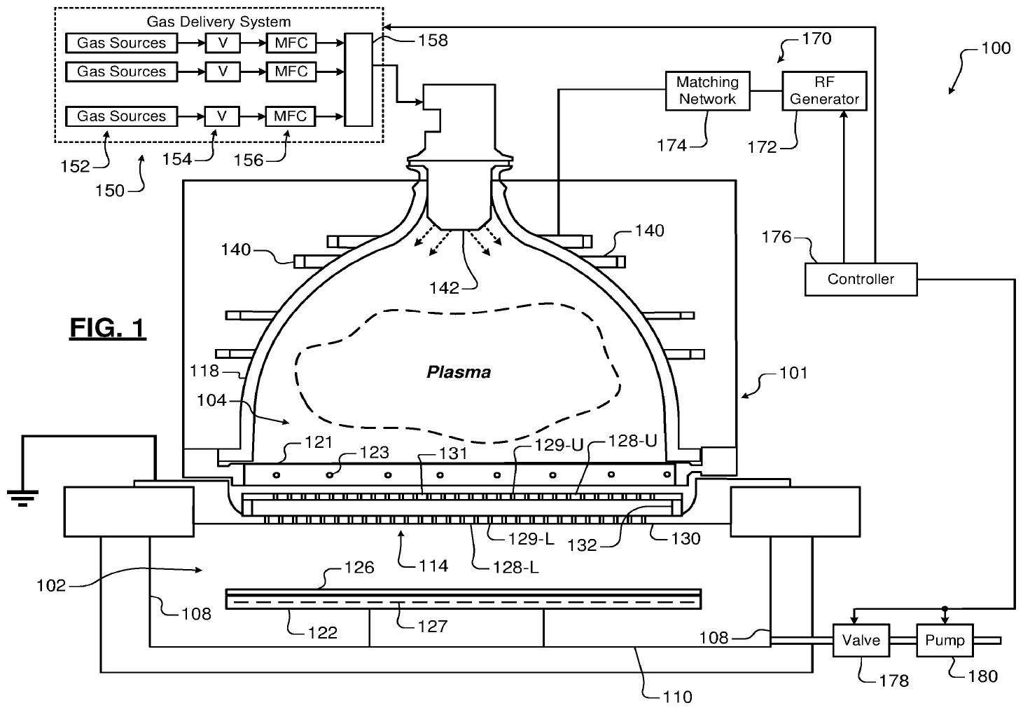

Referring now to FIG. 1, a substrate processing system 100 includes a substrate processing chamber 101. Although the substrate processing chamber 101 is shown as an inductively coupled plasma (ICP) based system, the examples disclosed herein may be applied to other types of substrate processing systems such as transformer coupled plasma (TCP) or downstream plasma systems.

The substrate processing chamber 101 includes a lower chamber region 102 and an upper chamber region 104. The lower chamber region 102 is defined by chamber sidewall surfaces 108, a chamber bottom surface 110, and a lower surface of a gas or plasma distribution device such as a showerhead assembly including a showerhead 114. For example, the showerhead 114 may be configured to function as a dual ion and/or UV filter/blocker.

The upper chamber region 104 is defined by an upper surface of the showerhead 114 and an inner surface of a dome 118. In some examples, the dome 118 rests on a first annular support 121 including one or more spaced holes 123 for delivering process gas to the upper chamber region 104. In some examples, the process gas is delivered by the one or more spaced holes 123 in an upward direction at an acute angle relative to a plane including the showerhead 114, although other angles/directions may be used. A gas flow channel in the first annular support 121 may be used to supply gas to the one or more spaced holes 123.

The substrate support 122 is arranged in the lower chamber region 102. In some examples, the substrate support 122 includes an electrostatic chuck (ESC), although other types of substrate supports can be used. A substrate 126 is arranged on an upper surface of the substrate support 122 during processing such as etching. In some examples, a temperature of the substrate 126 may be controlled by heating elements (or a heater plate) 127, an optional cooling plate with fluid channels and one or more sensors (not shown), although any other suitable substrate support temperature control system may be used.

In some examples, the showerhead 114 includes a lower plate 128-L with N₁ through holes 129-L. The showerhead 114 includes an upper plate 128-U with N₂ through holes 129-U. In some examples, the lower and upper plates 128-L and 128-U include planar portions 130 and 131, respectively, that are arranged parallel to one another. In some examples, the lower and upper plates 128-L and 128-U are connected to a reference potential such as ground (as shown in FIG. 1). In other examples, the lower and upper plates 128-L and 128-U may be connected to a positive or negative DC reference potential. The upper and lower plates 128-U and 128-L can be biased by the same reference potential or different reference potentials. Components of the showerhead 114 including, but not limited to, the upper and lower plates 128-U and 128-L include a coating in accordance with the principles of the present disclosure as described below in more detail.

The upper plate 128-U may be supported above the lower plate 128-L by an annular ring 132 (or supported in a similar spaced relationship in another manner). Alternately, the lower plate 128-L may be supported below the upper plate 128-U by the annular ring 132 (or supported in a similar spaced relationship in another manner). In still other examples, the upper plate 128-U and the lower plate 128-L are independently supported by chamber walls or one or more other processing chamber components in a spaced relationship.

One or more inductive coils 140 may be arranged around an outer portion of the dome 118. When energized, the one or more inductive coils 140 create an electromagnetic field inside of the dome 118. In some examples, an upper coil and a lower coil are used. A gas injector 142 injects one or more gas mixtures from a gas delivery system 150. The gas delivery system 150 includes one or more gas sources 152, one or more valves 154, one or more mass flow controllers (MFCs) 156, and a mixing manifold 158, although other types of gas delivery systems may be used.

In some examples, the gas injector 142 includes a center injection location that directs gas in a downward direction and one or more side injection locations that inject gas at one or more angles with respect to the downward direction. In some examples, the gas delivery system 150 delivers a first portion of the gas mixture at a first flow rate to the center injection location and a second portion of the gas mixture at a second flow rate to the side injection locations of the gas injector 142. In other examples, different gas mixtures are delivered by the gas injector 142. In some examples, the gas delivery system 150 delivers tuning gas to other locations in the processing chamber.

A plasma generator 170 may be used to generate RF power that is output to the one or more inductive coils 140. Plasma 190 is generated in the upper chamber region 104. In some examples, the plasma generator 170 includes an RF generator 172 and a matching network 174. The matching network 174 matches an impedance of the RF generator 172 to the impedance of the one or more inductive coils 140. A valve 178 and a pump 180 may be used to control pressure inside of the lower and upper chamber regions 102, 104 and to evacuate reactants.

A controller 176 communicates with the gas delivery system 150, the valve 178, the pump 180, and/or the plasma generator 170 to control flow of process gas, purge gas, RF plasma and chamber pressure. In some examples, plasma is sustained inside the dome 118 by the one or more inductive coils 140. One or more gas mixtures are introduced from a top portion of the substrate processing chamber 101 using the gas injector 142 (and/or holes 123).

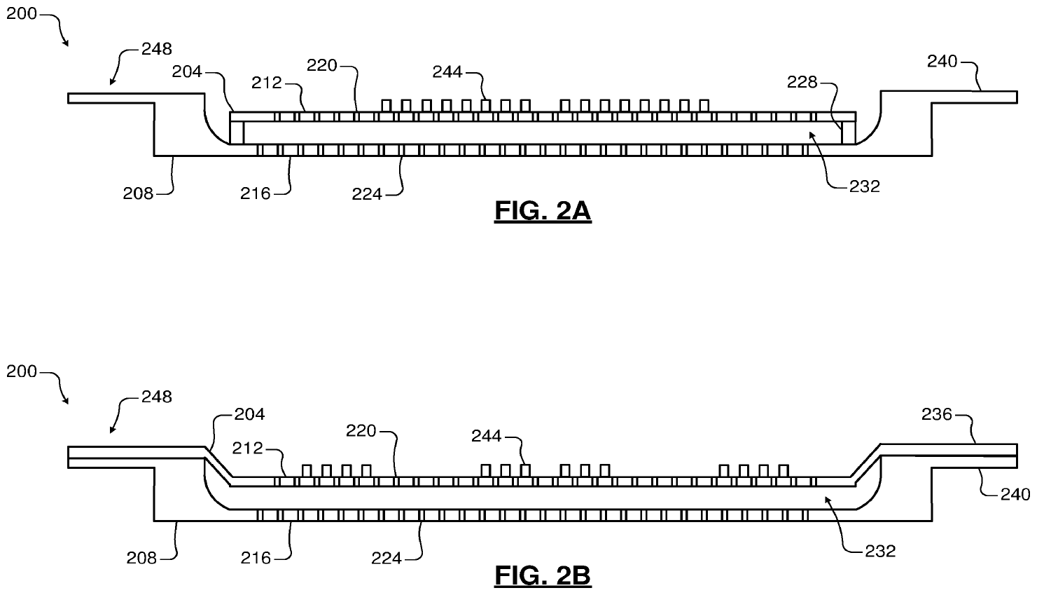

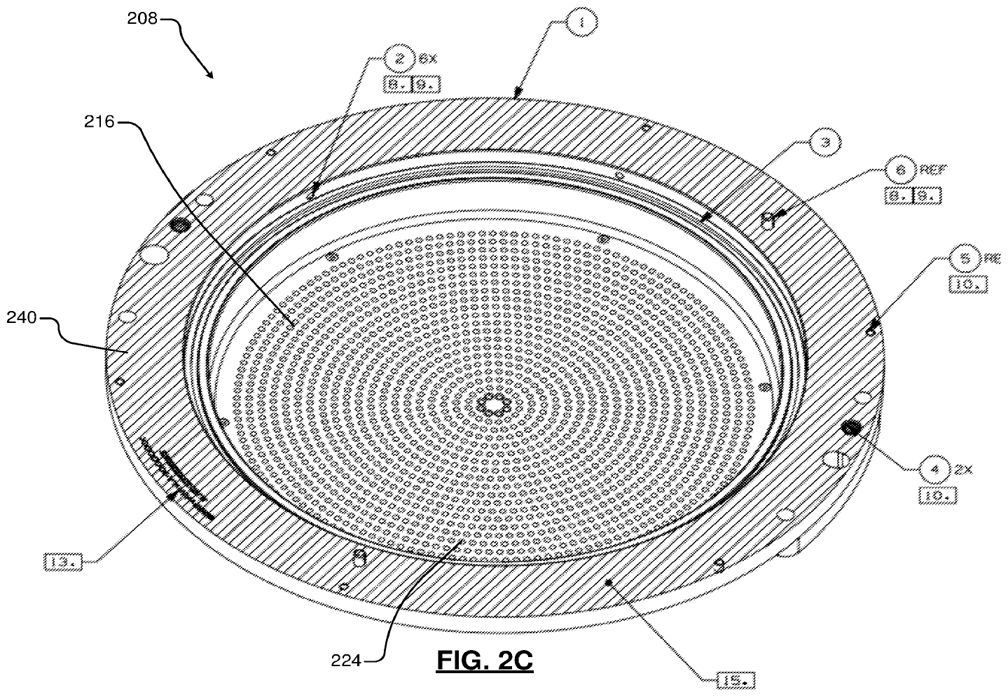

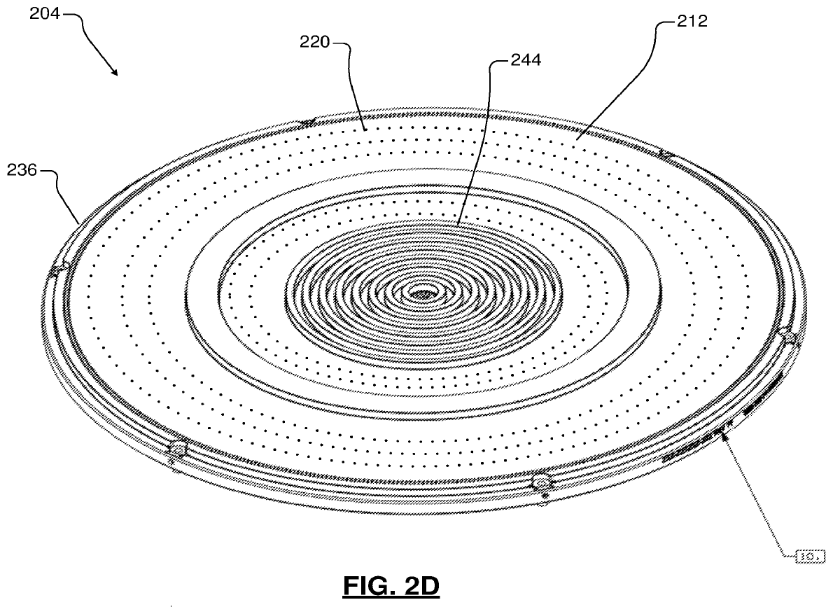

FIGS. 2A, 2B, 2C, and 2D show examples of a showerhead 200 including an upper plate 204 and a lower plate 208. The upper plate 204 and the lower plate 208 may be comprised of aluminum, have aluminum-coated surfaces, etc. Although shown as separate components, in some examples the upper plate 204 and the lower plate 208 may be implemented as a single, integrated component. Planar portions 212 and 216 of the upper plate 204 and the lower plate 208 include respective through holes 220 and 224. As shown in FIG. 2A, the upper plate 204 is supported in a spaced relationship above the lower plate 208 on an annular ring 228 to define a plenum 232 between the planar portions 212 and 216. As shown in FIG. 2B, the upper plate 204 includes an outer flange or rim 236 that is supported on an outer flange or rim 240 of the lower plate 208 to define the spaced relationship.

In some examples, the through holes 220 are not aligned (i.e., not aligned in a vertical direction) with the through holes 224 to eliminate direct line-of-sight from an upper chamber region, through the plenum 232, and into a lower chamber region. For example, the through holes 220 may be arranged in a different pattern or configuration than the through holes 224. As shown in FIGS. 2C and 2D, respectively, the through holes 224 of the lower plate 208 and the through holes 220 of the upper plate 204 are arranged in a plurality of concentric rings. The through holes 224 may have a same or different diameter as the through holes 220. Similarly, the through holes 224 may have a same or different quantity, density (i.e., pitch or spacing), and/or pattern than the through holes 220. In some examples, the upper plate 204 may include one or more annular rims or ridges 244 separating the through holes 220 into a plurality of different regions.

A conformal coating is applied to and/or created on surfaces of the upper plate 204 and/or the lower plate 208 in accordance with the principles of the present disclosure as described below in more detail. In one example, the surfaces of the upper plate 204 and the lower plate 208 are coated using a conformal process, such as a conformal ALD process. In another example, a conformal surface treatment such as a fluoroconversion process is performed on the surfaces of the upper plate 204 and the lower plate 208. For example, overall interior surface areas of the through holes 220 and 224 are greater than the flat/planar surface areas of the upper plate 204 and the lower plate 208. Accordingly, conformal processes ensure that the interior surfaces of the through holes 220 and 224 are coated to achieve desired radical recombination coefficients.

Typically, recombination with ions of process materials (e.g., fluorine) is desired to maintain a consistent number of ions reaching the substrate. For example, quartz has a relatively low recombination rate with fluorine and therefore is not preferred as a base material for the showerhead. Conversely, surfaces of aluminum components (which may include native oxides) may have a greater recombination rate and reduce the amount of ions that pass through the showerhead and reach the substrate. In other words, consistent recombination rates are generally desirable (e.g., as opposed to recombination rates that increase or decrease over time). However, exposure to fluorine over time increases the aluminum fluoride content of the surface of aluminum and, correspondingly, increases recombination rates to undesirable levels. A pre-applied coating such as the aluminum fluoride coating of the present disclosure prevents further fluoridation of the surface to maintain desired recombination rates. In other words, applying or creating an aluminum fluoride coating having a desired composition, thickness, and recombination coefficient prior to exposure to process materials maintains a desired recombination coefficient and rate.

One or more portions of the upper plate 204 and/or the lower plate 208 (e.g., portions in an outer edge region 248) may be DC grounded, electrically coupled to an RF or other power source, etc. In these examples, the portions that are configured to be DC grounded comprise bare aluminum to facilitate electrical communication. In other words, the portions of the upper plate 204 and/or the lower plate 208 that are configured to be DC grounded do not include the aluminum fluoride coating.

In some examples, the upper plate 204 and the lower plate 208 are comprised of aluminum or an aluminum alloy that includes (e.g., is doped with) one or more alloying elements configured to form a diffusion barrier layer between the aluminum surfaces and the aluminum fluoride coating. The alloying elements may include, but are not limited to, magnesium (Mg) and silicon (Si). The diffusion barrier layer limits reaction between the aluminum surface and additional fluorine and diffusion of additional fluorine into the aluminum.

For example, the upper plate 204 and the lower plate 208 are comprised of an aluminum alloy that includes 0 to 0.6% Si and 0.1 to 2.5% Mg. In one example, the aluminum alloy includes 0 to 0.3% Si and 0.3 to 1.2% Mg. During the conformal ALD process or the fluoroconversion process, the Mg in the aluminum alloy diffuses toward surfaces of the upper plate 204 and the lower plate 208. For example, increased temperatures (e.g., temperatures greater than 200 degrees Celsius) cause the Mg to diffuse toward the surfaces of the aluminum substrate. The Mg reacts with the fluorine to form the diffusion barrier layer (e.g., an MgF₂ diffusion barrier layer having a thickness of 0.1 to 0.5 microns) between the aluminum surface and the aluminum fluoride coating.

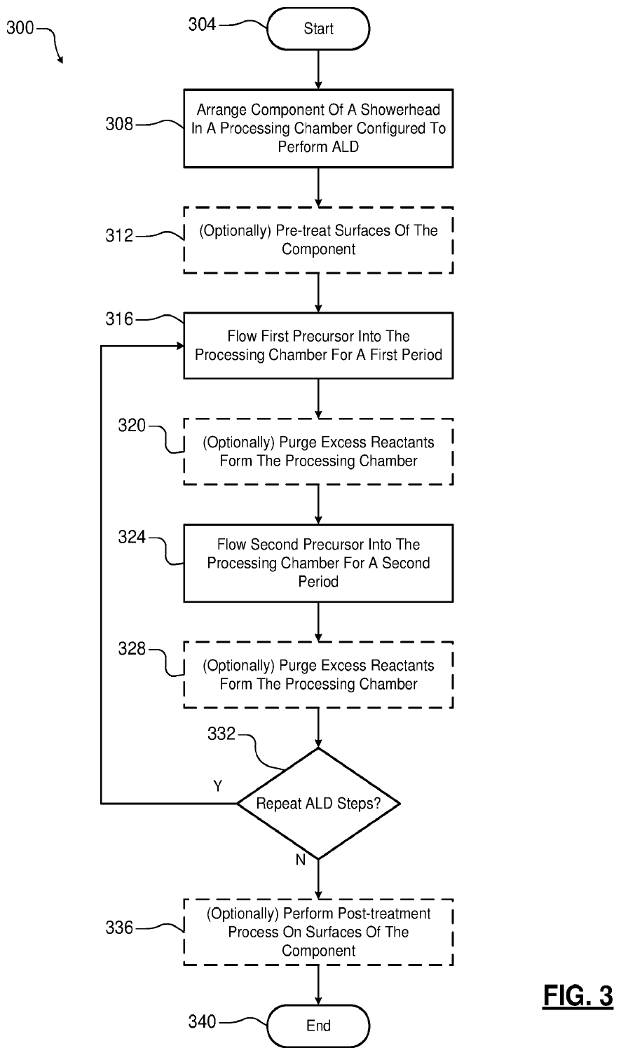

Referring now to FIG. 3, one example method 300 for applying a coating to components of a showerhead using a conformal ALD process according to the present disclosure begins at 304. At 308, a component of the showerhead (e.g., the upper plate 204 or the lower plate 208) is arranged in a processing chamber configured to perform ALD. For example, the component comprises a base material of aluminum. In one example, the base material is an aluminum alloy comprising Mg (e.g., 0.3 to 1.2% Mg). The aluminum alloy may include Si (e.g., less than or equal to 0.3% Si).

In some examples, one or more portions of the component (e.g., portions in the outer edge region 248) may not be exposed to prevent deposition of the coating on the one or more portions. For example, the component may be arranged in a fixture configured to expose only selected portions of the component while covering other portions of the component. At 312, the surfaces of the component may be optionally pre-treated (e.g., cleaned or conditioned, thermally treated, plasma treated, etc.) to condition the surfaces for ALD. In examples where the component is comprised of an aluminum alloy including Mg, the pre-treatment may cause the Mg to diffuse toward the surfaces of the component.

At 316, a first precursor or reactant is flowed into the processing chamber for a first period. For example, the first precursor includes the base material of the component (e.g., aluminum) and may include, but is not limited to, aluminum chloride (AlCl₃). The first precursor may be pulsed or continuously provided during the first period. At 320, the processing chamber may be optionally purged (e.g., using an inert gas) to remove excess reactants from the processing chamber.

At 324, a second precursor or reactant is flowed into the processing chamber for a second period. For example, the second precursor includes at least one target material corresponding to a process material used in plasma that the showerhead will be exposed to. For example only, for use in plasma processes including fluorine, the second precursor includes a fluorine-containing material such as, but not limited to, titanium fluoride (e.g., TiF₄) or tantalum fluoride (e.g., TaF₅). The second precursor may be pulsed or continuously provided during the second period.

The second precursor reacts with the first precursor to form a conformal layer on the surfaces of the component. For example, the second precursor reacts with the first precursor to form an aluminum fluoride coating. The materials of the first precursor and the second precursor described above are provided for example only and other materials may be used to form the aluminum fluoride coating. In one example, a plasma-based ALD process may be performed using a sulfur fluoride (e.g., sulfur hexafluoride (SF₆)) and an organoaluminum (e.g., Al(CH₃)₃) to form the aluminum fluoride coating. At 328, the processing chamber may be optionally purged to remove excess reactants from the processing chamber. In examples where the component is comprised of an aluminum alloy including Mg, the Mg reacts with fluorine to form a diffusion barrier layer (e.g., an MgF₂ diffusion barrier layer) between the surface of the component and the aluminum fluoride coating.

At 332, the method 300 (e.g., the controller 176) determines whether to repeat one or more ALD steps. For example, the method 300 may determine whether a desired thickness of the deposited layer has been reached. For example only, the desired thickness may be in a range of 10 to 200 nm. If true, the method 300 continues to 316. If false, the method 300 continues to 336.

At 336, a post-treatment process is optionally performed on the surfaces of the component. For example, the post-treatment process may include, but is not limited to, a thermal treatment (e.g., annealing), a plasma treatment, etc. The method 300 ends at 340.

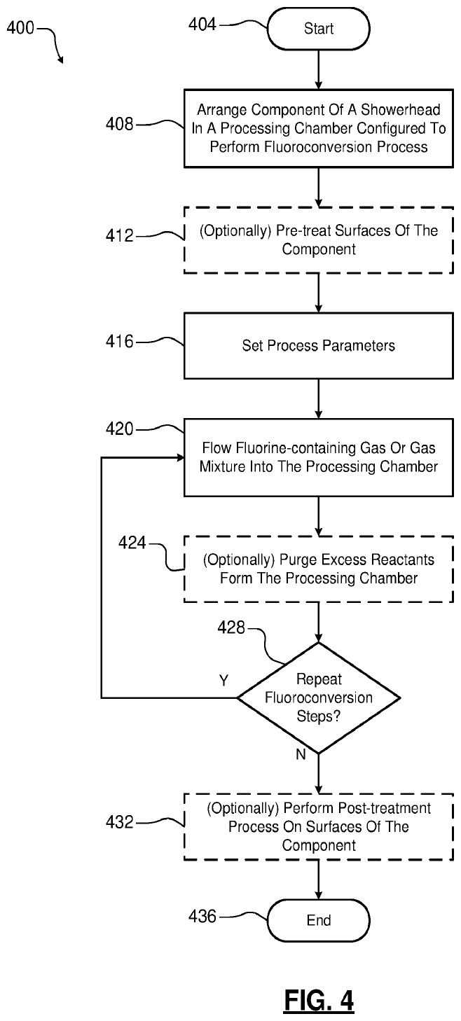

Referring now to FIG. 4, an example method 400 for performing a fluoroconversion process to create a conformal aluminum fluoride coating on components of a showerhead according to the present disclosure begins at 404. At 408, a component of the showerhead (e.g., the upper plate 204 or the lower plate 208) is arranged in a processing chamber configured to perform a fluoroconversion process. For example, the component comprises a base material of aluminum. In one example, the base material is an aluminum alloy comprising Mg (e.g., 0.3 to 1.2% Mg). The aluminum alloy may include Si (e.g., less than or equal to 0.3% Si).

In some examples, one or more portions of the component (e.g., portions in the outer edge region 248) may not be exposed to prevent creation of the coating on the one or more portions. For example, the component may be arranged in a fixture configured to expose only selected portions of the component while covering other portions of the component. At 412, the surfaces of the component may be optionally pre-treated (e.g., cleaned or conditioned, thermally treated, plasma treated, etc.) to condition the surfaces for fluoroconversion. In examples where the component is comprised of an aluminum alloy including Mg, the pre-treatment may cause the Mg to diffuse toward the surfaces of the component.

At 416, the method 400 (e.g., the controller 176) sets one or more process parameters. For example, a pressure and temperature of the processing chamber are selected to facilitate the fluoroconversion process. Pressure may be set in a range of 100 to 5000 mTorr and temperature may be set in a range of 20 to 650 degrees Celsius. At 420, a fluorine-containing gas or gas mixture is flowed into the processing chamber for a first period. The fluorine-containing gas may include, but is not limited to, nitrogen trifluoride (NF₃), carbon tetrafluoride (CF₄), difluorine (F₂), methyl fluoride (CHₓF_{y}, where x and y are greater than or equal to one), sulfur hexafluoride (SF₆), and/or chlorine trifluoride (ClF₃). For example, the gas may be pulsed or flowed continuously during the first period. In some examples, plasma may be generated within the processing chamber during the first period. The first period may be between 15 and 50 RF hours. The gas reacts with the aluminum to form an aluminum fluoride coating having a crystal lattice structure. In some examples, the coating may be amorphous. In examples where the component is comprised of an aluminum alloy including Mg, the Mg reacts with fluorine to form a diffusion barrier layer (e.g., an MgF₂ diffusion barrier layer) between the surface of the component and the aluminum fluoride coating.

At 424, the processing chamber may be optionally purged (e.g., using an inert gas) to remove excess reactants from the processing chamber. At 428, the method 400 (e.g., the controller 176) determines whether to repeat one or more fluoroconversion steps. For example, the method 428 determines whether a desired thickness of the deposited layer has been reached. For example only, the desired thickness may be in a range of 20 nm to 5 microns. In some examples, the desired thickness is in a range of 0.5 to 2.0 microns. If true, the method 400 continues to 420. If false, the method 400 continues to 432. At 432, a post-treatment process is optionally performed on the surfaces of the component. The method 400 ends at 436.

Although generally described with respect to an ion-blocking showerhead assembly, systems and methods according to the principles of the present disclosure may also be implemented in other types of processing chambers and corresponding components. For example, the fluoroconversion process may be applied on surfaces of components (e.g., an aluminum inner ground electrode assembly, outer electrode assembly, plasma confinement shroud, etc.) of a processing chamber configured to perform dielectric etching (e.g., a capacitively-coupled processing chamber configured to perform low temperature cryo etching).

For example, the fluoroconversion process according to the present disclosure may be used to convert surfaces of selected components to a conformal aluminum fluoride layer (e.g., an aluminum fluoride layer having a thickness between 10 nm and 10 microns and, in some examples, a thickness between a range of 0.5 and 2.0 microns). In some examples, the surface prior to fluorination may have intentional surface patterning to facilitate adhesion to etching byproducts. The aluminum fluoride layer is a stable, mixed amorphous and crystalline layer that is resistant to mechanical and chemical alteration caused by exposure to plasma. For example, the aluminum fluoride layer is stable (i.e., resistant to mechanical and chemical alteration caused by exposure to gases including, but not limited to, fluorine, halides, chlorine, bromine, carbon-halogen-fluorine gases, etc) and provides a controlled surface roughness on outer surfaces of the components. For example, the surface roughness (Ra) of the component prior to the fluoroconversion process may have a range between 2.5 and 25 μm. The aluminum fluoride layer is further resistant to delamination and decohesion from the surfaces of the components.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1-30. (canceled)

31. A component of a processing chamber in a substrate processing system, the component comprising:
a base material comprising aluminum, the base material having one or more surfaces;
a diffusion barrier layer formed on the surfaces of the base material, wherein the diffusion barrier layer includes magnesium and fluorine (F); and
a coating formed on the surfaces, wherein the diffusion barrier layer is arranged between the surfaces and the coating, and wherein the coating includes fluorine.

32. The component of claim 31, wherein the base material is comprised of an aluminum (Al) alloy including magnesium (Mg)

33. The component of claim 32, wherein the diffusion barrier layer is comprised of MgF₂.

34. The component of claim 33, wherein the diffusion barrier layer has a thickness of 0.1 to 0.5 μm.

35. The component of claim 33, wherein the coating is comprised of AlF₃.

36. The component of claim 31, wherein the coating has a thickness in a range of 20 nm to 5 μm.

37. The component of claim 31, wherein the coating has a thickness in a range of 10 nm to 200 nm.

38. The component of claim 31, wherein the coating has a crystal lattice structure.

39. The component of claim 31, wherein the component is a showerhead of the processing chamber.

40. The component of claim 39, wherein the showerhead comprises:
an upper plate; and
a lower plate, wherein
at least one of the upper plate and the lower plate is comprised of the base material,
the diffusion barrier layer is formed on surfaces of the at least one of the upper plate and the lower plate, and
the coating is formed on the surfaces of the at least one of the upper plate and the lower plate.

41. A showerhead for a processing chamber in a substrate processing system, the showerhead comprising:
an upper plate;
a lower plate,
wherein at least one of the upper plate and the lower plate is comprised of an aluminum (Al) alloy including magnesium (Mg);
a diffusion barrier layer formed on surfaces of at least one of the upper plate and the lower plate, wherein the diffusion barrier layer includes magnesium and fluorine (F); and
a coating formed on the surfaces, wherein the diffusion barrier layer is arranged between the surfaces and the coating, and wherein the coating includes fluorine.

42. The showerhead of claim 41, wherein the diffusion barrier layer is comprised of MgF₂ and the coating is comprised of AlF₃.

43. A method of performing a fluoroconversion process to apply a coating to surfaces of a component of a substrate processing system, the method comprising:
arranging the component within a processing chamber, wherein the component comprises a base material;
setting at least one process parameter of the processing chamber;
selecting a fluorine-containing gas, wherein the fluorine-containing gas is selected to react with the base material on surfaces of the component; and
flowing the fluorine-containing gas into the processing chamber for a first period, wherein the fluorine-containing gas reacts with the base material on the surfaces of the component to form the coating on the surfaces, and wherein the coating is comprised of (i) the base material of the component and (ii) fluorine.

44. The method of claim 43, wherein the base material of the component is aluminum and the coating comprises aluminum fluoride.

45. The method of claim 43, wherein the fluorine-containing gas includes at least one of nitrogen trifluoride (NF), carbon tetrafluoride (CF₄), difluorine (F₂), methyl fluoride (CH₄₋ₓFₓ, where x is an integer from 1 to 3), sulfur hexafluoride (SF), and chlorine trifluoride (ClF₃).

46. The method of claim 43, wherein at least one of:
the at least one process parameter is a pressure within the processing chamber and the pressure is set in a range of 100 to 5000 mTorr;
the at least one process parameter is a temperature within the processing chamber and the temperature is set in a range of 20 to 650 degrees Celsius; and
the coating has a thickness in a range of 20 nm to 5 microns.

47. The method of claim 43, further comprising generating plasma within the processing chamber during the first period.

48. The method of claim 43, wherein the component is a showerhead comprising an upper plate and a lower plate.

49. The method of claim 43, wherein the coating has a crystal lattice structure.

50. The method of claim 43, wherein the base material of the component is an aluminum alloy comprising magnesium, and wherein flowing the fluorine-containing gas into the processing chamber reacts with the magnesium to form a diffusion barrier layer between the surfaces of the component and the coating.
